(19) United States
(12) Patent Application Publication
(10) Pub. No.: US 2010/0188268 A1
(43) Pub. Date: Jul. 29, 2010

(54) Touchpad

(75) Inventors: Raphael Grignani, Santa Monica, CA (US); Mike Kruzeniski, Santa Monica, CA (US); Mattias Andersson, London (GB)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/439,533

(22) PCT Filed: Sep. 1, 2006
(86) PCT No.: PCT/EP06/08544

§ 371 Date: Mar. 15, 2010

(51) Int. Cl. H03K 17/94

(52) U.S. Cl. 341/22; 341/20

(57) ABSTRACT

A touchpad based on polar coordinates, in which the angular position and the radial position are transformed into a one-dimensional signal. The progressiveness of the relation between the angular position and the one-dimensional signal is a function of the radial position. The touchpad may have two discrete curved sections with different input sensitivity. The touchpad may also be provided with a central select key.

### FIELD OF THE INVENTION

The present invention relates to a touchpad for user input in electronic devices, in particular to touchpads that have a curved shape and/or are based on polar coordinates, and more particularly to a mobile electronic device having a touchpad.

### BACKGROUND OF THE INVENTION

U.S. Pat. No. 7,046,230 discloses a portable/mobile media player having a touchpad with a circular shape. The input from the touchpad in the form of a fingertip being moved over the touchpad is e.g. used for controlling a scrolling function. In this device a swirling is transformed into a linear scrolling movement. Alternatively a radial or tangential finger movement is transformed into a linear scrolling movement.

An advantage of the swirling based finger movement control is that a user is able to easily and rapidly transverse a lengthy list of media items in a scrolling function.

With the ever-increasing amounts of information that are handled on these type of mobile electronic devices there is a desire for a further improved user control over functions like scrolling.

### DISCLOSURE OF THE INVENTION

On this background, it is an object of the present invention to provide a touchpad with improved user control. This object is achieved by providing an electronic device comprising a touchpad based on polar coordinates, a processor coupled to the touchpad, wherein the processor is configured to combine both the angular coordinate and the radial coordinate received from the touchpad and transforms these two coordinates into a single input variable.

By combining the radial coordinate and the angular coordinate an extra dimension is added to the user control over the change in the input arrival. Thus, the flexibility of use of the touchpad is increased.

Preferably, the input variable is a one dimensional variable.

There may be a relation with a variable progressiveness between the angular coordinate and the input variable.

The processor can be configured to change the progressiveness of the relation between the angular coordinate and the input as a function of the radial coordinate. By providing a variable progressiveness, becomes possible to provide fast less precise scrolling and slow more precise scrolling, i.e. an inconsistent with a plurality of sensitivities to input, thereby being better adapted to handle input in different circumstances.

The processor can also be configured to use the input variable in a control function for controlling the various applications associated with the device.

The control function may correspond to a change of setting function that allows the value of a setting of the device to be changed.

The electronic device may further include a display connected to the processor, the display being configured to display text and graphics to a user of the electronic device, the display being supported by the housing.

Preferably, the control function corresponds to a scrolling function that allows content displayed on the display to be moved across the display and out of sight on one side of the screen as new content is added on the opposite side of the screen.

The control function may also correspond to a navigation function.

The electronic device may further include a key distinct from the keypad placed substantially at the center of the coordinate system.

It is another object of the invention to provide a method in which a rotary or swirling finger movement over a touchpad that is operated with polar coordinates is used as input for an electronic device, comprising associating an angular motion of a finger over the touchpad with a change in a one dimensional parameter in accordance with a function with a variable progressiveness, changing the progressiveness of the function as a function of the radial position of the object moving over the touchpad.

Preferably, the progressiveness increases with an increase in the radial position.

Alternatively, the progressiveness may decrease with an increase in the radial position.

The one dimensional parameter can be used to control a function associated with the electronic device. This function can be a scrolling function.

It is another object of the present invention to provide a touchpad based on polar coordinates, comprising at least two distinct and substantially concentrically arranged curved touchpad areas.

By providing two distinct touchpad areas, it is possible to create an input device that has two different functionalities.

Preferably, the at least two curved touchpad areas are distinct by a non-touch sensitive area therebetween.

The curved touchpad areas can be distinct by optical differentiation between the respective surfaces of the at least two curved touchpad areas. The optical differentiation may be realized through a color differentiation and/or a graphical differentiation and/or texture material.

Alternatively, the at least two curved touchpad areas can be distinct by texture differentiation between the respective surface areas of the at least two curved touchpad areas.

Preferably, one or more of the curved touchpad areas have the shape of closed curves.

The touchpad may have a button or key disposed at the center region of the touchpad.

It is another object of the present invention to provide an electronic device comprising a housing that encloses internally various electronic components including a processor and an input device is described here above, wherein the input sensitivity of the curved touchpad areas is different from one another.

The processor may be configured to differentiate the input sensitivity of the curved touchpad areas.

Preferably, the processor is configured to associate an input signal with a swirling movement on an object over one or more of the curved touchpad areas.

Further, the processor can be configured to associate a movement of an object over the outer curved touchpad area or areas over a given angle with a first given change of an input parameter and to associate a movement of an object over to the inner curved touchpad or areas over the given angle with a second given change of the input parameter, wherein the second given change is either smaller or larger than at first given change.

It is another object of the present invention to provide an electronic device comprising an input device including at least a first and a second substantially concentrically arranged curved touchpad areas, a processor coupled to the input device, the processor being configured to associate an angular motion of an object over the first curved touchpad area with a change in a one dimensional parameter of the device in accordance with a function with first level progressiveness, and the processor being configured to associate an angular motion of an object over the second curved touchpad area with a change in a one dimensional parameter of the device in accordance with the function with a second level progressiveness different from the first level progressiveness.

Preferably, the level of progressiveness associated with the first curved touchpad area is larger than the level of progressiveness associated with the second curved touchpad area.

Alternatively, the level of progressiveness associated with the second curved touchpad area is larger than the level of progressiveness associated with the first curved touchpad area.

The one dimensional parameter can be used to control a function associated with the electronic device. This function may be a scrolling function.

The processor can be configured to associate a third level of progressives different from the first- and second level of progressives to the change in the one dimensional parameter when both touchpad areas are touched simultaneously.

It is another object of the present invention to provide a computer readable medium including at least computer program code for interacting with a graphical user interface produced on a display device of an electronic device, the computer readable medium including at least: computer program code for receiving a rotational movement associated with a user input action; radial position associated with a user input action and computer program code for combining the rotational movement input and the radial position input into a one dimensional input parameter.

The computer readable medium may further include computer program code for applying the one dimensional input parameter to a function associated with the electronic device.

It is yet another object of the present invention to provide a method in which a rotary or swirling finger movement over a touchpad that is operated with polar coordinates is used as input for an electronic device, the touchpad being provided with an array of lights under the touchpad or adjacent to the borders of the touchpad comprising sensing the position and/or velocity of the finger movement over the touchpad, activating and deactivating one or more of the lights in the array as a function of the position and/or velocity sensed by the touchpad.

By activating lights under, or near to the touchpad, the user gets a direct optical feedback that the touchpad recognizes the user input and the position in which the touchpad is touched correctly. Thereby user confidence is improved and acceptance of the technology is enhanced.

The method may further comprise activating the lights in accordance with a moving pattern that follows an object moving over the touch surface of the touch sensor.

Preferably, the method further comprises continuing the movement of the moving pattern when the object moving over the touch surface is retracted from the touch surface.

The movement of the object over the touch pad be a swirling movement and the moving pattern of light activation gives an observer the impression that the touchpad is a spinning wheel with mechanical inertia.

Preferably, the method further comprises stopping the movement of the moving pattern when an object is brought into contact with the touch surface again.

The method may also comprise activation of one or more lights closest to an object touching the touchpad.

It is a further object of the present invention to provide a capacitive touchpad comprising an at least semi-translucent touch surface, a plurality of lights disposed below that transparent touch surface, the lights being arranged such that they are visible trough the touch surface of the touchpad when they are active.

The capacitive touchpad may have at least one outer contour of the touchpad shaped as a curve, and at least some of the plurality of lights may be disposed on a curve concentric with the curved outer contour.

Preferably, the lights can be individually activated and deactivated.

The lights can be activated and deactivated in accordance with a moving pattern.

Preferably, the moving pattern follows the movement of an object moving over the touchpad.

The pattern may keep moving with substantially unchanged speed when the object moving over the touch surface is withdrawn from the touch surface.

The pattern may stop moving when an object touches the touch surface again.

Preferably, the one or more lights closest to an object touching the touch surface are activated.

The capacitive touchpad may have an elongated shape to form a straight or curved scrollbar.

The moving pattern may repeat from the opposite end of said elongated touchpad when the pattern reaches one of the ends of said touchpad.

The movement of said moving pattern may decelerate after said object moving over the touchpad surface has been withdrawn. Preferably, the movement of said moving pattern decelerates and given enough time comes to a stop by itself without further user interaction.

The decelerating movement of the pattern may give an observer the impression of a moving mechanical system that is slowed down by friction.

Further objects, features, advantages and properties of the touchpad, method and computer readable medium according to the invention will become apparent from the detailed description.

### BRIEF DESCRIPTION OF THE DRAWINGS

In the following detailed portion of the present description, the invention will be explained in more detail with reference to the exemplary embodiments shown in the drawings, in which:

FIG. 1 is a plane front view of a mobile phone with a touchpad according to a first embodiment of the invention,

FIG. 2 is a block diagram illustrating the general architecture of a mobile phone if FIG. 1 in accordance with the present invention,

FIG. 3 is a diagrammatic representation in the form of a front view of an electronic device including a touchpad according of the invention,

FIG. 4 is a front view of the device of FIG. 3 with another embodiment of the touchpad according to the invention,

FIG. 5 is a front view of the device of FIG. 3 with yet another embodiment of the touchpad according to the invention,

FIG. 6 is a diagrammatic representation of a further embodiment of the touchpad according to the invention,

FIG. 7 is a diagrammatic representation of the hardware of the touchpad according to the invention,

FIG. 8 is a flow chart of a touchpad operation method according to the invention,

FIG. 9 is a another flow chart of a touchpad operation method according to the invention, and

FIG. 10 is a front view of another embodiment of the touchpad according to the invention on an electronic device.

### DETAILED DESCRIPTION OF PREFERRED EMBODIMENTS

In the following detailed description, the touchpad, the mobile electronic device, the method and the software product according to the invention in the form of a cellular/mobile phone will be described by the preferred embodiments.

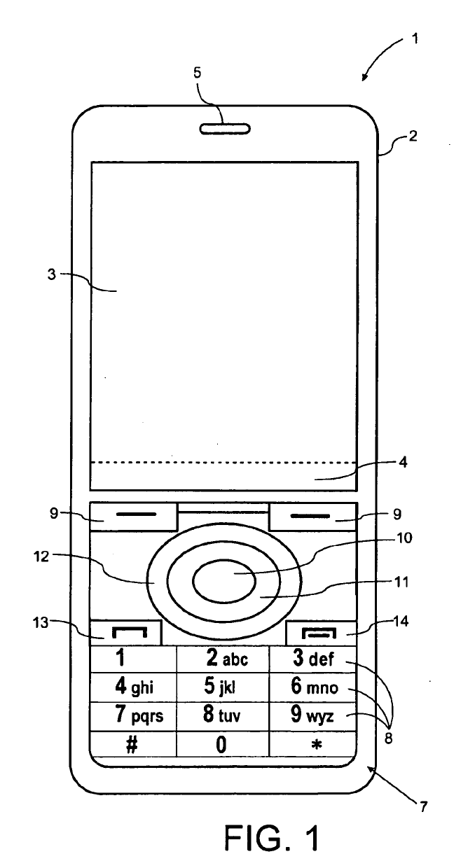

FIG. 1 illustrates a first embodiment of a mobile terminal according to the invention in the form of a mobile telephone 1 by a front view. The mobile phone 1 comprises a user interface having a housing 2, a display 3, an on/off button (not shown), a speaker 5 (only the opening is shown), and a microphone 6 (not visible in FIG. 1). The phone 1 according to the first preferred embodiment is adapted for communication via a cellular network, such as the GSM 900/1800 MHz network, but could just as well be adapted for use with a Code Division Multiple Access (CDMA) network, a 3G network, or a TCP/IP-based network to cover a possible VoIP-network (e.g. via WLAN, WIMAX or similar) or a mix of VoIP and Cellular such as UMA (Universal Mobile Access).

The keypad 7 has a first group of keys 8 as alphanumeric keys, by means of which the user can enter a telephone number, write a text message (SMS), write a name (associated with the phone number), etc. Each of the twelve alphanumeric keys 8 is provided with a figure “0-9” or a sign “#” or “*”, respectively. In alpha mode each key is associated with a number of letters and special signs used in the text editing.

The keypad 2 has additionally a second group of keys comprising two softkeys 9, two call handling keys (offhook key 13 and onhook key 14), a touchpad with an inner area formed by an inner touch ring 11 for e.g. scrolling fast, and an outer area formed by an outer touch ring 12 for e.g. scrolling slow and precise, as well as a select/activate key 10. The constructional details of the touchpad will described further below. The function of the softkeys 9 depends on the state of the phone, and navigation in the menu is performed by using the touch ring 11 and/or outer touch ring 12 of the touchpad. The present function of the softkeys 9 is shown in separate fields (soft labels) in a dedicated area 4 of the display 3, just above the softkeys 9. The two call handling keys 13,14 are used for establishing a call or a conference call, terminating a call or rejecting an incoming call. This key layout is characteristic for e.g. the Nokia 6230i™ phone.

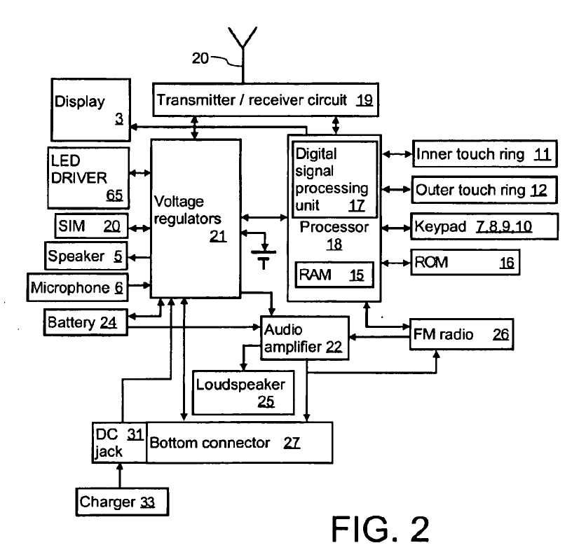

A releasable rear cover (not shown) gives access to the SIM card 20 (FIG. 2), and the battery pack 24 (FIG. 2) in the back of the phone that supplies electrical power for the electronic components of the mobile phone 1.

The mobile phone 1 has a flat display 3 that is typically made of an LCD with optional back lighting, such as a TFT matrix capable of displaying color images. A touch screen may be on top of the conventional LCD display.

FIG. 2 illustrates in block diagram form the general architecture of a mobile phone 1 constructed in accordance with the present invention. The processor 18 controls the operation of the terminal and has an integrated digital signal processor 17 and an integrated RAM 15. The processor 18 controls the communication with the cellular network via the transmitter/receiver circuit 19 and an internal antenna 20. A microphone 6 coupled to the processor 18 via voltage regulators 21 transforms the user's speech into analogue signals, the analogue signals formed thereby are A/D converted in an A/D converter (not shown) before the speech is encoded in the DSP 17 that is included in the processor 18. The encoded speech signal is transferred to the processor 18, which e.g. supports the GSM terminal software. The digital signal-processing unit 17 speech-decodes the signal, which is transferred from the processor 18 to the speaker 5 via a D/A converter (not shown).

The voltage regulators 21 form the interface for the speaker 5, the microphone 6, the LED drivers 65 (for the LEDS backlighting the keypad 7 and the display 3, and in some embodiments below the touchpad), the SIM card 20, battery 24, the bottom connector 27, the DC jack 31 (for connecting to the charger 33) and the audio amplifier 33 that drives the (hands-free) loudspeaker 25.

The processor 18 also forms the interface for some of the peripheral units of the device, including a Flash ROM memory 16, the graphical display 3, the keypad 7, the select key 10, the inner touch ring 11, the outer touch ring 12, and an FM radio 26.

The touchpad is configured to provide one more control functions for controlling various applications associated with the mobile phone or other type of mobile electric device. For example, the touch initiated control function may be used to move an object or perform an action on the display 3 or to make selections or issue commands associated with operating the mobile phone or other mobile electric device. Normally, the touchpad is arranged to receive input from a finger moving over to the surface of the touchpad in order to implement the touch initiated control function. The touchpad receives input from a rotary or swirling finger motion over the inner touch ring 11 and/or the outer touch ring 12. By way of example, tapping a finger on the touch surface may initiate a control function, similar to the select function of key 10.

In one embodiment, the control function corresponds to a scrolling feature. For example, in case of a mobile phone the moving finger may initiate a control function for scrolling through a list of phone book entries displayed on the display 3. The term “scrolling” as used herein generally pertains to moving displayed data or images (e.g., text or graphics) across a display area of the display 3 and out of sight on one side of the display area as new content is added on the opposite side of the display area. The array of data may be treated as an endless loop, so that it is possible to continue scrolling when the end of the data has been reached.

The viewing area may be the entire viewing area of the display 3 or it may be only a portion of the display 3 (e.g. a window frame).

The direction of scrolling may be widely varied. For example, scrolling may be implemented vertically (as up or down) or horizontally (as left or right). In the case of vertical scrolling, when the user scrolls down, each set of new data appears at the bottom of the viewing area and all other sets of data move up one position. If the viewing area is full, the top set of data moves out of the viewing area. In one implementation the scrolling feature may be used to move graphical user interface vertically or horizontally in order to bring more data into view on the display 3. By way of example, the scrolling feature may be used to help browse through files stored in the electronic device, through images displayed on the display of the electronic device, a few songs stored in the electronic device or through phonebook entries stored in the device. The direction that the finger moves may be arranged to control the direction of scrolling. For example, the touchpad may be arranged to move the graphical user interface vertically up when the finger is moved anticlockwise and vertically down when the finger is moved clockwise.

According to an embodiment, the processor 18 in the electronic device is configured to associate a larger progressiveness with the finger movement detected on the inner ring 11 than the movement detected on the outer ring 12. A given amount of finger movement over the inner touch 11 ring will allow fast scrolling through a long list, whilst a similar amount of finger movement over the outer touch ring 12 will allow precise control over the scrolling movement, e.g. for selecting the exact item that is to be activated in the scrolling list.

The touchpad generally consists of a touchable outer surface for receiving a finger for manipulation on the touchpad. Although not shown in FIGS. 1-5, beneath the touchable outer surface is a sensor arrangement. The touchpad includes a plurality of sensors that are configured to be activated as the finger passes over them. In the simplest case, an electrical signal is produced each time the finger passes a sensor. The number of signals in a given timeframe may indicate the location, direction, speed and acceleration of the finger on the touchpad, i.e., the more signals, the more the user has moved his or her finger. In most cases, the signals are monitored by an electronic interface that converts the number, combination and frequency of the signals into location, direction, speed and exploration information. This information may then be used by the electronic device 1 to perform the desired control function, for example on the display 3.

The position of the touchpad relative to the housing 2 may be widely varied. For example, the touchpad may be placed on any external surface (e.g. top, side, front or back) of the housing 2 that is accessible to the user during manipulation of the electronic device 1. In most cases the touch sensitive surface of the touchpad is completely exposed to the user. In the illustrated embodiments, the touch sensitive surface of the touchpad is substantially flush with the external surface of the housing 2.

The shape of the touchpad may also be widely varied. For example, the touchpad may be circular, rectangular, triangular, and the like. In general, the outer perimeter of the shaped touchpad defines the working boundary of the touchpad. In the illustrated embodiment, the touchpad is oval. Oval touchpads allow a user to continue to swirl a finger in a free manner, i.e. the finger can be rotated to 360° of rotation without stopping. Furthermore, the user can rotate his or her finger eventually from all sides thus giving it more range of finger positions. More particular, the touchpad is annular, i.e. shaped like or formed as a ring. When annular, the inner and outer parameter of the shaped touchpad define the working boundary of the touchpad. Within these boundaries, the touchpad comprises according to an embodiment the inner touch ring 11 and the outer touch ring 12.

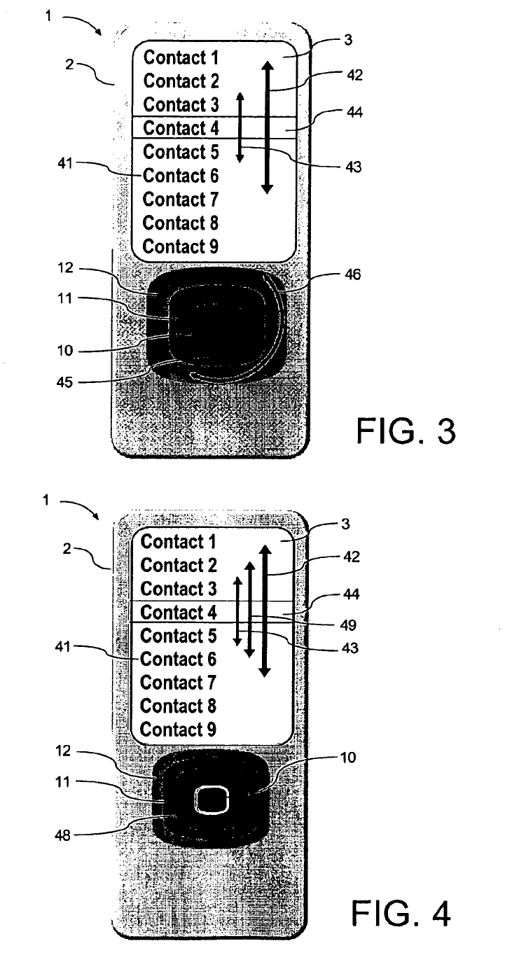

FIGS. 3-5 illustrate the operation of the touchpad in accordance with different embodiments of the invention. In these embodiments the operation of the device is explained with reference to a scrolling function. It is however understood that the input signal from the touchpad can be used for any other control function in the electronic device, such as the changing of a setting, for example a volume setting. In all of these embodiments, the user is linearly scrolling (as shown by arrows 42 and 43) a list of phonebook entries 41 displayed on the display 3 via a slider bar 44. Referring to FIG. 3, and in accordance with one embodiment of the invention, the touchpad can be continuously actuated by a simple swirling motion of the finger over the inner touch ring 11 (as shown by arrow 45) and/or the outer touch ring 12 (as shown by arrow 46). By swirling, it is meant that the finger moves in an arcuate or circular manner.

For example, the finger may rotate relative to an imaginary axis. In particular, the finger can be rotated to 360° of rotation without stopping. This form of motion may produce continuous or incremental scrolling on the display 3.

The processor 18 in the electronic device 1 is configured to associate different levels of progressiveness with the inner touch ring 11 and the outer touch ring 12. In one embodiment, the progressiveness of the inner touch ring 11 is higher than the progressiveness of the outer touch ring 12. This embodiment is illustrated in FIG. 3 by the linear arrow 42 that indicates the larger scrolling movement caused by the swirling finger movement in accordance with curved arrow 45 on the inner touch ring 11 and by the linear arrow 43 that indicates the smaller scrolling movement caused by the swirling finger movement in accordance with the curved arrow 46 on the outer touch ring 12.

In accordance with another embodiment (not shown) the processor 18 in the electronic device is configured to associate a higher level of progressiveness with the outer touch ring 12 and a lower level of progressiveness with the inner touch ring 11. In any of the embodiments with a plurality of touch rings, the processor 18 is configured to associate a third and different level of progressiveness with a simultaneous activation of both touch rings.

According to one embodiment this third level of progressiveness is lower than the level of progressiveness associated with the touching of the inner touch ring 11 and the outer touch ring 12 individually.

FIG. 4 shows another embodiment of the invention, that is essentially identical with the embodiment of FIG. 3, except that the touch sensor includes three substantially concentric touch rings: an inner touch ring 11, an intermediate touch ring 48 and an outer touch ring 12. In this embodiment, the processor 18 is configured to associate a different level of progressiveness for the scrolling function with each of the touch rings. These different levels may, as shown in FIG. 4 by the arrows 42, 43 and 49, have a high level of progressiveness for the inner ring 11, a medium level of progressiveness for the intermediate ring 48 and a low level of progressiveness for the outer ring 12. The level of progressiveness may, however, be distributed differently, in accordance with the particular circumstances in which the touch ring is used

In this embodiment, the processor can be configured to associate further levels of progressiveness when two or three of the touch rings are touched simultaneously.

According to the embodiment of FIGS. 3 and 4 the distinct areas of the touchpad are optically differently shaded by different coloring. Alternatively, the distinct areas of the touchpad can be optically differentiated by graphics.

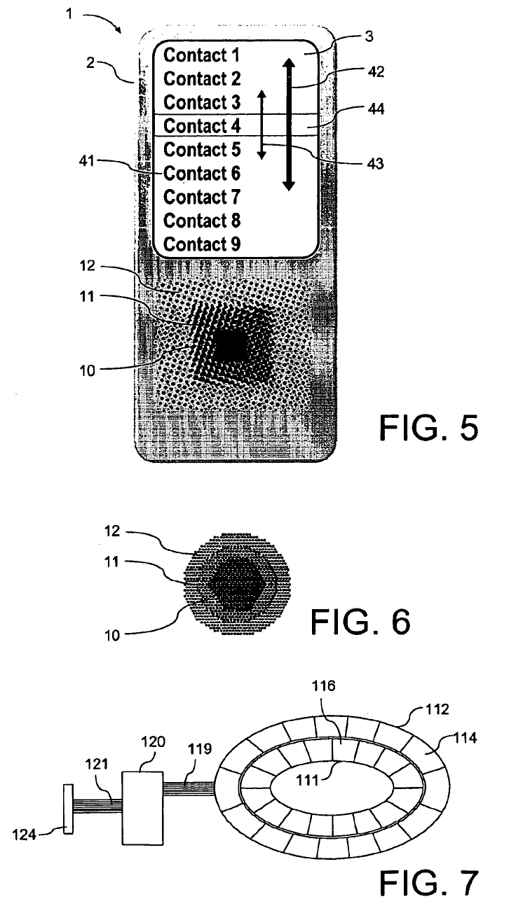

With reference to FIGS. 5 and 6 the inner touch ring 11 and the outer touch ring 12 are optically differentiated by a change in density of texture, e.g. through the tactile feedback. The optical and texture differentiation may also be combined (not shown). FIG. 6 illustrates a circular shape for the outer contours of the inner touch ring 11 and the outer touch ring 12. In this embodiment the inner and outer touch rings are differently shaded for the user through a variation in texture density.

FIG. 7 illustrates the hardware components of a touchpad according to an embodiment of the invention. The touchpad is divided into several independent and spatially distinct segments 114 and 116. Any number of segments may be used. In this embodiment, each of the segments represents a polar angle that specifies the angular position of the zone in the plane of the inner touch ring 111 or the outer touch ring 112. The inner touch ring 111 is provided with a plurality of sensor segments 116 that are angularly distributed and substantially equally spaced. The outer touch ring 112 is provided with a plurality of center segments 114 that are also angularly distributed and substantially equally spaced. By way of example, the segments 114,116 may be positioned at 3° increments all the way around the inner touch ring 111 and the outer touch ring 112.

Each of the segments has an associated sensor disposed therein for detecting the presence of an object such as a finger. The sensors may be widely varied. For example, the sensors may be based on the resistive sensing, surfing surface acoustic sensing, pressure sensing, optical sensing, capacitive sensing and the like.

In general, when an object approaches a segment 111,114 and more particularly, a sensor, a position signal is generated that informs the processor 18 that the object is at a specific angular position on the inner touch ring 111 and/or the outer touch ring 112. The touchpad also includes a control assembly 120 that is coupled to the touchpad via a cable 119. The control assembly 120 is configured to acquire the position signals from the sensors and to supply the acquired signals to the processor 18 via a cable 121 that connects to a printed circuit board (not shown) on which the processor 18 is mounted through a connector 124.

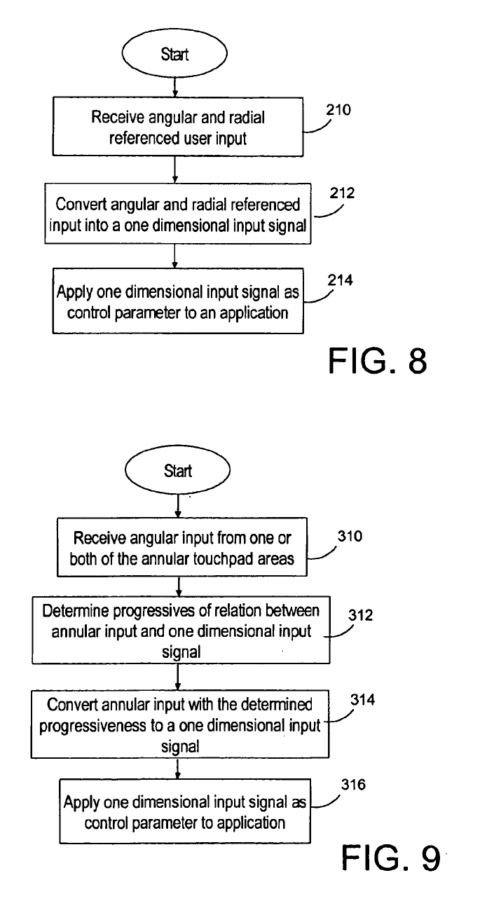

FIG. 8 is a flow chart of a touchpad method in accordance with the one embodiment of the invention. The method allows a user to interact with a graphical user interface of a computing device. The touchpad method starts at block 210 with receiving angular and radial referenced input. The input may be received by the processor 18 illustrated in FIG. 2. In this embodiment, the radial input is substantially variable and the touchpad (not shown) has a plurality of sensors distributed and spaced over the radial extent of the touchpad for providing a variable radial position signal. In this embodiment a discrete distribution of the touchpad into radial zones, as shown in the figures is not required. The user input can therefore in this embodiment of the invention be a combined radial referenced input and angular referenced input, as for example produced by an angular user action, such as a finger angularly moving over the touchpad with a variable radial position.

Following block 210, the touchpad method proceeds to block 212 where the angular and radial referenced user input is converted to a one-dimensional input signal. This step may include associating an angular motion of a finger over the touchpad with a change in a one dimensional input or control parameter in accordance with a function with a variable progressiveness.

The function may be specific to the application in which it is to be used. Further, this step may include changing the progressiveness of the function as a function of the radial position of the object moving over the touchpad, i.e. the user input. For example, the progressiveness is increased with an increase in the radial position, so that a faster change of the one dimensional control parameter is obtained at outer positions on the touchpad with a slower change in the one dimensional control parameter at inner positions on the touchpad. In another example the progressiveness decreases with an increase in the radial position, so that a slower change of the one dimensional control parameter is obtained at outer positions on the touchpad (for precise control) and a faster change in the one dimensional control parameter at inner positions on the touchpad (for fast changes, such as in scrolling quickly to a position far away in a list).

The one-dimensional control input can for example be the control over a setting of the electronic device, a scrolling function, or a navigational function, such as in the navigation in a videogame associated with the electronic device. The conversion may be implemented by the processor 18 illustrated in FIG. 2. Following block 212, the touchpad method proceeds to block 214 where the one-dimensional input signal is applied as a control parameter to an application associated with the electronic device.

For example, the control object, such as a slider bar may be linearly moved from a first item to a second item on a list or it may be moved to multiple items on the list (e.g. scrolling). The application of the control parameter is generally implemented when the processor illustrated in FIG. 2 supplies the one-dimensional input signal to the graphical user interface on the display 3. Alternatively, the processor 18 may supply the one-dimensional input signal to the control process of the settings of the electronic device, such as volume setting, display brightness setting, clock settings, calendar settings, etc.

FIG. 9 is a flow chart of a touchpad method in accordance with another embodiment of the invention. The method allows a user to interact with a graphical user interface of a computing device. The touchpad method starts at block 310 with receiving angular and radial referenced input. The input may be received by the processor 18 illustrated in FIG. 2. In this embodiment, the radial input is discretely distributed in accordance with the number of touchpad areas or rings, such as for example shown in FIGS. 1,3-7.

Following block 310, the touchpad method proceeds to block 312 where the progressiveness of the relation between the annular input and the one dimensional input signal is determined. This determination may be carried out by the processor 18 shown in FIG. 2 via identification of the respective touch ring or rings that is/are touched by the finger of the user. Next, in step 314 the angular and radial referenced user input is converted to a one-dimensional input signal according to the determined progressiveness.

Following step 314, the touchpad method proceeds by applying the one-dimensional input signal as a control parameter to an application associated with electronic device. The one-dimensional control input signal can for example be used to the control over a setting of the electronic device, a scrolling function, or a navigational function, such as in the navigation in a videogame associated with the electronic device. The conversion may be implemented by the processor 18 illustrated in FIG. 2.

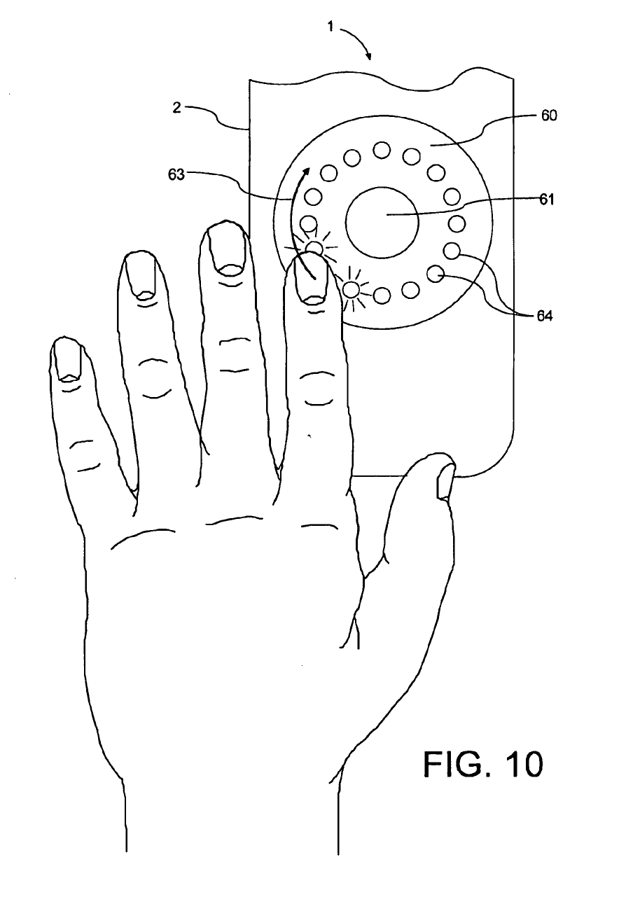

FIG. 10 illustrates yet another embodiment of the touchpad according to the present invention. In this embodiment the touchpad may use both angular and radial input, however the radial input is not necessarily included. Thus, the output signal of the touchpad may be simply an angular position, angular velocity and/or angular acceleration information. The touchpad according to this embodiment is shown as mounted on the housing 2 of an electronic device 1. The touchpad includes a touch sensitive touch surface 60 that has an annular shape with a circular outer parameter and a circular inner perimeter, wherein the circular inner parameter is occupied by a select key 61. The touch surface 60 is translucent or at least semi-translucent and an array of lights 64, for example LEDs, is arranged below the touch surface 60. The array of lights 64 has a circular shape in this embodiment, but it should be understood that the lights 64 can be arranged in any other pattern. Preferably, the LEDs 64 cannot be seen by an observer when they are not active, whilst the light emitted by the LEDs 64 can be seen by an observer when the LEDs are active. The touch surface may be provided with a pattern of translucent or semi-translucent windows that give a particular shape to the light of the LEDs that can be seen when they are active. Thus, even though round LEDs are used the visual pattern could be made up by rectangles, triangles or any other geometrical shapes. A pattern of touch sensors, similar to the construction described with reference to FIG. 7 is provided below the touch surface 60. The touch sensors and the LEDs 64 are connected to a processor 18 as shown in FIG. 2.

The processor 18 is configured to selectively activate the LEDs 64 as a function of the position and or velocity of the user input sensed by the touchpad. In an example of such a function the lights are activated in accordance with a moving pattern that follows an object moving over the touch surface of the touch sensor. FIG. 10 illustrates such an example, in which a number (here three) LEDs closest to the position at which a finger of a user touches the touch surface 60 are activated (one of the three active LEDs 64 cannot be seen in FIG. 10 since it is obscured by a finger tip).

When the user moves his/her finger, for example in accordance with the arrow 63 the processor will determine which of the three LEDs are located closest to a present position of the finger on the touchpad, and thereby the three active LEDs appear to move together with the fingertip moving over the touch surface 60. This activation provides the user with optical feedback that the touchpad is functioning correctly and recognizing accurately the angular user input. It should be understood that any other pattern of active LEDs could be used to support the operation of the touchpad, and that it does not need to be the three LEDs closest to the fingertip that are activated. For example, the three LEDs positioned furthest away, i.e. the one, two, three or other number of LEDs positioned diagonally opposite to the present position of the fingertip can be activated instead of or in combination with the three or the number of LEDs closest to the fingertip.

The user will often move his/her finger with a given angular velocity over the touch surface 60. This will result in the pattern of active LEDs moving with the same angular velocity.

According to an embodiment the pattern of active light continues its movement when the user retracts his finger from the touch surface. Preferably, the pattern of active lights continues the movement initially with the same velocity as the last detected velocity of the moving fingertip over the touch surface 60. This will give an observer, such as the user himself/herself the impression that the touchpad is a spinning wheel with mechanical inertia. The processor 18 will control such movement of the pattern of active LEDs. According to an embodiment of the invention the processor 18 is configured to slowly decrease the angular velocity of the moving pattern of active lights, so that an observer (such as the user) will get the impression of a spinning wheel with mechanical inertia that is exposed to the effect of friction and thereby slowly loses its inertia and comes eventually to a stop.

According to an embodiment of the invention the movement of the pattern of active LEDs and the corresponding change in the one-dimensional input signal is continued, as if the user is still swirling his/her finger over the touch surface. Thus, a user can give the imaginary wheel a “swing” and let the wheel spin for a while. For example, when the control function associated with the touchpad signal is a scrolling function, the processor 18 will continue the scrolling movement as a function of the angular velocity of the moving pattern of active LEDs.

According to another embodiment, the processor 18 is configured to stop the movement of the moving pattern of active LEDs when the user brings his/her fingertip into contact with the touch surface again. Thus, the user is able to stop the moving pattern and the scrolling movement by touching the touchpad again, when a desired position in the scrolled information is approaching or has been reached.

According to another embodiment (not shown) that is essentially identical to the embodiments described directly here above, the touchpad with the LEDs therebelow has an elongated shape to form a scrollbar. In this embodiment the moving pattern repeats from the opposite end of the elongated touchpad when the pattern reaches one of the ends of the touchpad after the object moving over the touch surface has been retracted.

The various aspects of the invention described above can be used alone or in various combinations. The invention is preferably implemented by a combination of hardware and software, but can also be implemented in hardware or software. The invention can also be embodied as computer readable code on a computer readable medium. Furthermore, although a scrolling feature is described, it should be noted that a scrolling feature is not the limitation and that the touchpad may be used to manipulate other features. For example, the touchpad may be used to adjust the volume control in an audio application. In addition, the touchpad may be used to advance to frames in a movie editing application. The touchpad may also be used in video game applications.

The invention has numerous advantages. Different embodiments or implementations may yield one or more of the following advantages. It should be noted that this is not an exhaustive list and there may be other advantages which are not described herein. One advantage of the invention is that a user is able to easily and rapidly transverse a lengthy list of media items, whilst also having precise control for slowly traversing the list of media items. Thus, the invention provides both fast and less precise control as well as slow and precise control. Another advantage of the invention is that the touchpad provides a visual feedback to the user, which improves user confidence. Another advantage of the present invention is that the touchpad allows an intuitive way to control an electronic device. Yet another advantage is that the present invention allows a touchpad to be used in a manner similar to mechanical control element that can be set into “swing” and exploit the effect of such imaginary mechanical inertia.

Although the present invention has been described in detail for purpose of illustration, it is understood that such detail is solely for that purpose, and variations can be made therein by those skilled in the art without departing from the scope of the invention.

For example, although the invention has been described in terms of a mobile phone, it should be appreciated that the invention may also be applied to other types of electronic devices, such as cameras, video recorders, music players, palmtop computers and the like. Moreover, certain aspects of the invention are not limited to handheld devices. For example, the touchpad may also be used in other computing devices such as a laptop computer. The touchpad may also be used as a stand-alone input device that connects to a desktop or portable computer. It should also be noted that there are many alternative ways of implementing the methods and apparatuses of the present invention. For example, although the touchpad has been described in terms of being actuated by a finger, it should be noted that other objects may be used to actuate in some cases. For example, a stylus or other object may be used in some configurations of the touchpad.

The term “comprising” as used in the claims does not exclude other elements or steps. The term “a” or “an” as used in the claims does not exclude a plurality. The single processor or other unit may fulfill the functions of several means recited in the claims.

The reference signs used in the claims shall not be construed as limiting the scope.

1. An electronic device comprising:
a touchpad based on polar coordinates
a processor coupled to said touchpad,
wherein said processor is configured to combine both the angular coordinate and the radial coordinate received from said touchpad and transforms these two coordinates into a single input/control variable.

2. An electronic device according to claim 1, wherein said input variable is a one dimensional variable.

3. An electronic device according to claim 1 or 2, wherein there is a relation with a variable progressiveness between the angular coordinate and the input variable.

4. An electronic device according to claim 3, wherein said processor is configured to change the progressiveness of the relation between the angular coordinate and the input as a function of the radial coordinate.

5. An electronic device according to any of claims 1 to 4, wherein said processor is configured to use the input variable in a control function for controlling the various applications associated with the device.

6. An electronic device according to claim 5, wherein the control function corresponds to a change of setting function that allows the value of a setting of the device to be changed.

7. An electronic device according to claim 5 or 6, further including a display connected to said processor, said display being configured to display text and graphics to a user of the electronic device, the display being supported by the housing.

8. An electronic device according to claim 7, wherein the control function corresponds to a scrolling function that allows content displayed on the display to be moved across the display and out of sight on one side of the screen as new content is added on the opposite side of the screen.

9. An electronic device according to claim 7, wherein the control function corresponds to a navigation function.

10. An electronic device according to any of claims 1 to 9, further including a key distinct from the keypad placed substantially at the center of the coordinate system.

11. A method in which a rotary or swirling finger movement over a touchpad that is operated with polar coordinates is used as input for an electronic device, comprising:
associating an angular motion of a finger over the touchpad with a change in a one dimensional parameter in accordance with a function with a variable progressiveness,
changing the progressiveness of said function as a function of the radial position of the object moving over the touchpad.

12. A method according to claim 11, wherein said progressiveness increases with an increase in the radial position.

13. A method according to claim 12, wherein said progressiveness decreases with an increase in the radial position.

14. A method according to any of claims 11 to 13, wherein, said one dimensional parameter is used to control a function associated with said electronic device.

15. A method according to claim 14, wherein said function is a scrolling function.

16. A touchpad based on polar coordinates, comprising at least two distinct and substantially concentrically arranged curved touchpad areas.

17. A touchpad according to claim 16, wherein said at least two curved touchpad areas are distinct by a non-touch sensitive area there between.

18. A touchpad according to claim 16 or 17, wherein said curved touchpad areas are distinct by optical differentiation between the respective surfaces of the at least two curved touchpad areas.

19. A touchpad according to claim 18, wherein said optical differentiation is a color differentiation and/or a graphical differentiation.

20. A touchpad according to any of claims 16 to 19, wherein said at least two curved touchpad areas are distinct by texture differentiation between the respective surface areas of the at least two curved touchpad areas.

21. A touchpad according to any of claims 16 to 20, wherein one or more of said curved touchpad areas have the shape of closed curves.

22. A touchpad according to any of claims 16 to 21, further having a button or key disposed at the center region of the touchpad.

23. An electronic device comprising:
a housing that encloses internally various electronic components including a processor that provide the device, and
an input device according to any of claims 16 to 22,
wherein the input sensitivity of the curved touchpad areas is different from one another.

24. An electronic device according to claim 23, wherein said processor is configured to differentiate the input sensitivity of the curved touchpad areas.

25. An electronic device according to claim 23, wherein said processor is configured to associate an input signal with a swirling movement on an object over one or more of said curved touchpad areas.

26. An electronic device according to claim 25, wherein said processor is configured to associate a movement of an object over the outer curved touchpad area or areas over a given angle with a first given change of an input parameter and to associate a movement of an object over the inner curved touchpad or areas over said given angle with a second given change of said input parameter, wherein said second given change is either smaller or larger than said first given change.

27. An electronic device comprising:
an input device including at least a first and a second substantially concentrically arranged curved touchpad areas,
a processor coupled to said input device,
said processor being configured to associate an angular motion of an object over the first curved touchpad area with a change in a one dimensional parameter of said device in accordance with a function with first level progressiveness, and
said processor being configured to associate an angular motion of an object over the second curved touchpad area with a change in a one dimensional parameter of said device in accordance with said function with a second level progressiveness different from said first level progressiveness.

28. An electronic device according to claim 27, wherein the level of progressiveness associated with the first curved touchpad area is larger than the level of progressiveness associated with the second curved touchpad area.

29. An electronic device according to claim 28, wherein the level of progressiveness associated with the second curved touchpad area is larger than the level of progressiveness associated with the first curved touchpad area.

30. An electronic device according to any of claims 27 to 29, wherein said one dimensional parameter is used to control a function associated with said electronic device.

31. An electronic device according to claim 30, wherein said function is a scrolling function.

32. An electronic device according to any of claims 27 to 31, wherein said processor is configured to associate a third level of progressives different from said first- and second level of progressives to the change in the one dimensional parameter when both touchpad areas are touched simultaneously.

33. A computer readable medium including at least computer program code for interacting with a graphical user interface produced on a display device of an electronic device, said computer readable medium including at least: computer program code for receiving a rotational movement associated with a user input action; radial position associated with a user input action and computer program code for combining the rotational movement input and the radial position input into a one dimensional input parameter.

34. A computer readable medium according to claim 33, further including computer program code for applying the one dimensional input parameter to a function associated with said electronic device.

35. A method in which a rotary or swirling finger movement over a touchpad that is operated with polar coordinates is used as input for an electronic device, said touchpad being provided with an array of lights under the touchpad or adjacent to the borders of the touchpad comprising:
sensing the position and/or velocity of the finger movement over the touchpad,
activating and deactivating one or more of said lights in said array as a function of the position and or velocity sensed by the touchpad.

36. A method according to claim 35, further comprising activating said lights in accordance with a moving pattern that follows an object moving over the touch surface of the touch sensor.

37. A method according to claim 36, further comprising continuing the movement of said moving pattern when said object moving over the touch surface is retracted from the touch surface.

38. A method according to claim 37, wherein the movement of said object over the touchpad is a swirling movement and said moving pattern of light activation gives an observer the impression that the touchpad is a spinning wheel with mechanical inertia.

39. A method according to claim 37 or 38, further comprising stopping movement of said moving pattern when an object is brought into contact with said touch surface again.

40. A method according to any of claims 37 to 39, comprising activation of one or more lights closest to an object touching the touchpad.

41. A capacitive touchpad comprising an at least semi-translucent touch surface, a plurality of individually and selectively activatable lights disposed below the transparent touch surface, said lights being arranged such that they are visible trough the touch surface of the touchpad when they are active.

42. A capacitive touchpad according to claim 41, wherein at least an outer contour of said touchpad is a curve, and at least some of said plurality of lights are disposed on a curve concentric with said curved out contour.

43. A capacitive touchpad according to claim 42, wherein said lights can be individually activated and deactivated.

44. A capacitive touchpad according to any of claims 41 to 44, wherein said lights are activated and deactivated in accordance with a moving pattern.

45. A capacitive touchpad according to claim 44, wherein said moving pattern follows the movement of an object moving over the touchpad.

46. A capacitive touchpad according to claim 44 or 45, wherein said pattern keeps moving with substantially unchanged speed when said object moving over the touch surface is withdrawn from the touch surface.

47. A capacitive touchpad according to claim 46, wherein said pattern stops moving when an object touches the touch surface again.

48. A capacitive touchpad according to any of claims 41 to 47, wherein one or more lights closest to an object touching the touch surface are activated.

49. A capacitive touchpad according to any of claims 41 to 48, wherein said touchpad has an elongated shape to form a scrollbar.

50. A capacitive touchpad according to claim 49, wherein the moving pattern repeats from the opposite end of said elongated touchpad when the pattern reaches one of the ends of said touchpad after the object moving over the touch surface has been retracted.

51. A capacitive touchpad according to any of claims 41 to 50, wherein the movement of said moving pattern decelerates after said object moving over the touchpad surface has been withdrawn.

52. A capacitive touchpad according to claim 51, wherein the movement of said moving pattern decelerates and given enough time comes to a stop by itself without further user interaction.

53. A capacitive touchpad according to claim 52, wherein the decelerating movement of said pattern gives an observer the impression of a moving mechanical system that is slowed down by friction.
